(19) United States
(12) Patent Application Publication
(10) Pub. No.: US 2005/0052122 A1
(43) Pub. Date: Mar. 10, 2005

(54) Electroluminescent display and method for manufacturing an electroluminescent display

(76) Inventors: Kazuaki Iwasawa, Tokyo (JP); Hideki Ookawa, Kanagawa-ken (JP)

Correspondence Address: Finnegan, Henderson, Farabow,;Garrett & Dunner, L.L.P., 1300 I Street, N.W., Washington, DC, 20005-3315, US

(21) Appl. No.: 10/895,381

(22) Filed: Jul. 21, 2004

(30) Foreign Application Priority Data
Jul. 22, 2003 (JP) 2003-200036

(51) Int. Cl. H05B 33/00

(52) U.S. Cl. 313/504; 313/506

(57) ABSTRACT

An electroluminescent display has a transparent substrate. A transparent positive electrode is formed on the transparent substrate. An inert metal film is formed on the transparent positive electrode. A hole transport layer on the inert metal film, includes a conductive polymer doped with a polymeric electrolyte containing a sulfone group. An emissive layer is formed on the hole transport layer.

### CROSS REFERENCE TO RELATED APPLICATION

This application is based upon and claims the benefit of priority from the prior Japanese Patent Application No. 2003-200036 filed on Jul. 22, 2003; the entire contents of which are incorporated herein by reference.

### FIELD OF THE INVENTION

The present invention relates to an electroluminescent display and a manufacturing method thereof, and more particularly to a polymer organic electroluminescent display and a manufacturing method thereof.

### DESCRIPTION OF THE RELATED ART

An electroluminescent display has a hole transport layer between an ITO (Indium Tin Oxide) film as an electrode and an emissive layer which emits light. A water-soluble electrically conductive polymer doped with a polymeric electrolyte containing a sulfone group, is generally used as the hole transport layer. Poly(4-styrenesulfonate) (PSS) and poly(3,4-ethylenedioxythiophene) (PEDOT), may be respectively used as the polymeric electrolyte and the electrically conductive polymer.

However, a PEDOT:PSS solution is such a strong acid whose PH ranges from 1 to 2, that the solution corrodes the ITO film when the solution is coated and dried on the ITO film to form a PEDOT:PSS film as the hole transport layer. Particularly, the ITO film is damaged at the dry process. The corrosion of the ITO film causes performance deterioration, i.e., decrease of luminous efficiency and shortening of operating time, of an electroluminescent display.

Further, a PSS molecule in the PEDOT:PSS film has an ionized SO₃H group, which causes a concentration gradient inside the PEDOT:PSS film where the concentration of PSS is higher at points closer to the surface of the ITO film. Therefore, the conductivity inside the film is nonuniform. As a result, hole injection efficiency of the PEDOT:PSS film deteriorates.

Furthermore, a barrier height (an energy barrier) for transporting holes between the PEDOT:PSS film and the ITO film, is 1.5 electron volts. Lowering the energy barrier of the boundary surface would be desirable to improve hole transport efficiency.

The 18th and 34th paragraphs in Japanese Patent Publication (kokai) No. 2002-260852, show forming an Au layer, Au having a high work function, on an ITO positive electrode A. Then a hole transport layer made up of low-molecular-weight N′, N′-diphenyl-N′, N′-(3-methylphenyl)-1,1′-biphenyl-4 and 4′-diamine (TPD), is formed for enhancing carrier injection efficiency and luminous efficiency.

However, the publication relates not to the polymer type which has a hole transport layer containing a polymer, but to the low molecule type of electroluminescent displays. Nothing about a polymeric hole transport layer containing a polymer such as the PEDOT:PSS which may corrode an ITO film or the like, is disclosed in the publication.

The 36th and 37th paragraphs of the publication additionally disclose the thickness between the Au layer as a positive electrode B and an Al layer as a negative electrode. According to the publication, the thickness is set to satisfy the resonance conditions of light. Hence, the Au layer serves as a mirror for light reflection (light interference). The Au layer thus reflects lights to resonate between the positive and negative electrodes. The thickness is specifically selected to range from 40 nm to 60 nm according to the 35th and 39th paragraphs, which means that light cannot pass through the layer.

### SUMMARY OF THE INVENTION

One aspect of the present invention is an electroluminescent display. The display comprises a transparent substrate, a transparent positive electrode on the transparent substrate, an inert metal film on the transparent positive electrode, a hole transport layer on the inert metal film, the hole transport layer includes a conductive polymer doped with a polymeric electrolyte containing a sulfone group, and an emissive layer on the hole transport layer.

Another aspect of the present invention is a method for manufacturing an electroluminescent display. The method comprises providing a positive electrode on a transparent substrate, providing a hole transport layer on the positive electrode, the hole transport layer includes a conductive polymer doped with a polymeric electrolyte including a sulfone group, and providing an emissive layer on the hole transport layer.

### BRIEF DESCRIPTION OF THE DRAWING

FIG. 1 is a schematic view of a polymer organic electroluminescent display.

FIG. 2 shows a transmissivity of Pt.

FIGS. 3A and 3B show PEDOT derivatives which can be used as a conductive polymer.

FIG. 4 shows a definition of a hole injection barrier (Eᵢₙⱼ)

FIGS. 5A and 5B respectively show Eᵢₙⱼ between Au and PEDOT:PSS, and Eᵢₙⱼ between ITO and PEDOT:PSS.

FIG. 6 shows Eᵢₙⱼ between ITO and Au, and between Au and PEDOT:PSS.

FIG. 7 shows intensity ratio of PSS against PEDOT.

### DETAILED DESCRIPTION OF EMBODIMENTS OF THE INVENTION

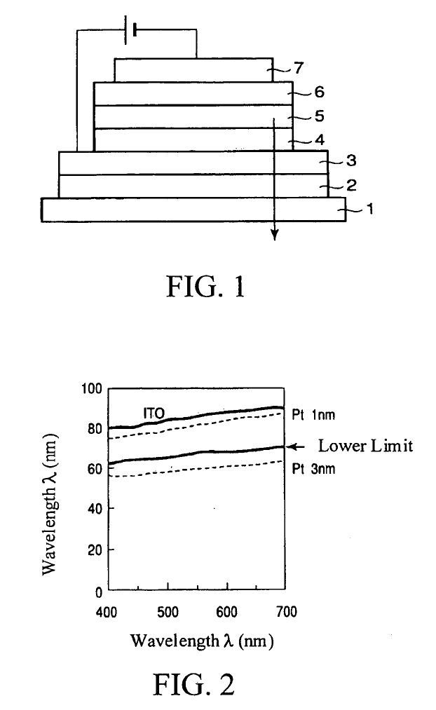

One embodiment of the invention is explained next with reference to FIGS. 1 to 4.

FIG. 1 is a schematic view of a polymer organic electroluminescent display.

A transparent substrate 1 is made of glass. A transparent electrode 2 such as an ITO electrode, is provided on transparent substrate 1. A thin film 3 whose thickness is set to permit light to pass through, is made of inert metal, and formed on transparent electrode 2. A hole transport layer 4 is formed on thin film 3 by coating and drying a water solution of a conductive polymer doped with a polymeric electrolyte including a sulfone group, on thin film 3. An emissive layer 5, an electron transport layer 6 and a negative electrode 7 are sequentially formed on hole transport layer 4 as shown in FIG. 1.

The inert metal is selected from Au, Pt, Rh, Ir or the like. The attenuation coefficients of light absorption of Au, Pt, Rh and Ir are respectively 2.7, 3.7, 4.9 and 4.3 at around 550 nm, which is the center of the visible band where a visibility of human beings is the highest.

With respect to the attenuation coefficients, the thickness of thin film 3 is preferably less than or equal to 3 nm. The thickness is more preferably in a range from 1 nm to 3 nm when thin film 3 is made of Au. When using Pt, a thickness ranging from 0.5 nm to 2.5 nm is more preferable, and when using Rh or Ir, a thickness ranging from 0.5 nm to 2.0 nm is more preferable.

FIG. 2 shows the transmissivity of Pt as an example. The transmissivities of Pt for thicknesses of 1 nm and 3 nm, are shown as dashed lines. The transmissivity of ITO electrode 2 is shown as a solid line. The lower limit of a transmissivity to permit light to pass through effectively, is also shown as a solid line.

The work functions of Au, Pt, Rh and Ir are 5.1 eV, 5.65 eV, 4.98 eV, and 5.27 eV, respectively.

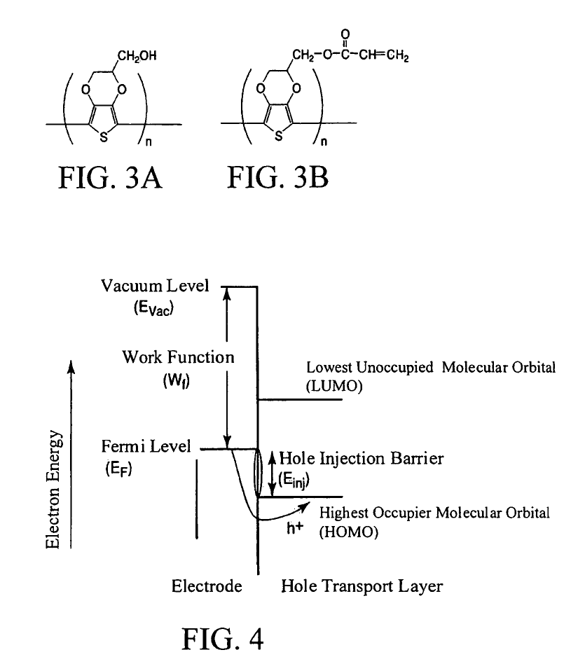

As for the polymeric electrolyte which constitutes hole transport layer 4, poly(4-styrenesulfonate) (PSS), or polyvinyl sulfonate, partially sulfonated polymer (beta hydroxy ether), partially sulfonated polybutadiene, may be used. Other polymeric electrolytes also can be used. As for the water soluble conductive polymer which constitutes hole transport layer 4, poly (3,4-ethylenedioxythiophene) (PEDOT), or poly(3,4-butylenedioxythiophene) may be used. Soluble PEDOT derivatives shown in FIGS. 3A and 3B or other water soluble conductive polymers, also can be used.

As for emissive layer 5, poly(p-phenylene vinylene), poly(3-alkyl thiophene), or poly(1,4-naphthalene vinyl) or the like can be used.

As for electron transport layer 6, polypyridine, poly(p-pyridyl vinylene), poly(3,4-dialkyl-1,6-phenylene ethylene) such as alkyl, methyl, ethyl, or propyl can be used.

As described above, transparent positive ITO electrode 2 is formed on transparent substrate 1. Thin film 3 whose thickness is set to permit visible light to pass through film 3, is formed on transparent substrate 1. A water solution of a conductive polymer doped with a polymeric electrolyte including a sulfone group as a dopant, is coated on thin film 3 before the coated water solution is dried for forming hole transport layer 4 of PEDOT:PSS.

According to the electroluminescent display above, light emitted from emissive layer 5 sequentially passes through hole transport layer 4, thin film 3, transparent electrode 2 and transparent substrate 1 as an arrow shows in FIG. 1.

In the conventional art where a hole transport layer is formed on a positive ITO electrode by directly coating and drying PEDOT:PSS or the like on the electrode, the ITO electrode is corroded due to the effect of the strong acid in PSS. In addition, ionization of a PSS molecule forms a SO₃H group which causes a concentration gradient inside the hole transport layer, where the concentration of PSS is higher at points closer to the surface of the ITO electrode. As a result, hole injection efficiency of the hole transport layer deteriorates.

As for the embodiment above, since inert metal is interposed between electrode 2 and hole transport layer 3, corrosion of electrode 2 is restrained. Further, the interposed inert metal alleviates the concentration gradient due to the ionization of a PSS molecule, so that the uniformity of the conductivity inside hole transport layer 4 can be enhanced. As a result, holes generated inside the inert metal in contact with hole transport layer 4, can be effectively injected into hole transport layer 4.

Furthermore, an energy barrier (a hole injection barrier) at the boundary surface between thin film 3 made of inert metal and hole transport layer 4 made from PEDOT:PSS or the like, is lowered. When the inert metal is, for example, Au, the energy barrier is 0.2 eV, which is lower than that (1.5 eV) at the boundary surface between a hole transport layer made from PEDOT:PSS and an ITO electrode. Holes generated in thin film 3, are therefore injected into hole transport layer 4 effectively.

A hole injection barrier (Eᵢₙⱼ) at the boundary surface between thin film (electrode) 3 made of inert metal and hole transport layer 4, is defined as shown in FIG. 4.

According to the embodiment above, light emitted from emissive layer 5 can be outputted from transparent substrate 1. Positive electrode 2 made from ITO can be restrained from corrosion. The injection efficiency of holes generated in thin film 3, into hole transport layer 4 is enhanced. Therefore a polymer organic electroluminescent display with higher luminous efficiency and longer operating time, can be provided.

A practical example is explained next.

First, a positive electrode with 500 nm thickness made from ITO, is provided on a glass substrate. Then, a thin film having 1 nm thickness made of Au, is deposited on the surface of the positive electrode. Secondly, being coated on the thin film, a water solution of PEDOT: PSS is dried to form a hole transport layer made from PEDOT:PSS. In the coating and drying process, the positive electrode (ITO) is prevented from corrosion by the solution because it is protected by the thin film of Au. Next, an emissive layer made of poly(p-phenylene vinylene) is formed on the hole transport layer. Then an electron transport layer made of polypyridine, is formed on the emissive layer. A negative electrode of Al is formed on the electron transport layer. As a result, an organic electroluminescent display such as shown in FIG. 1 is provided.

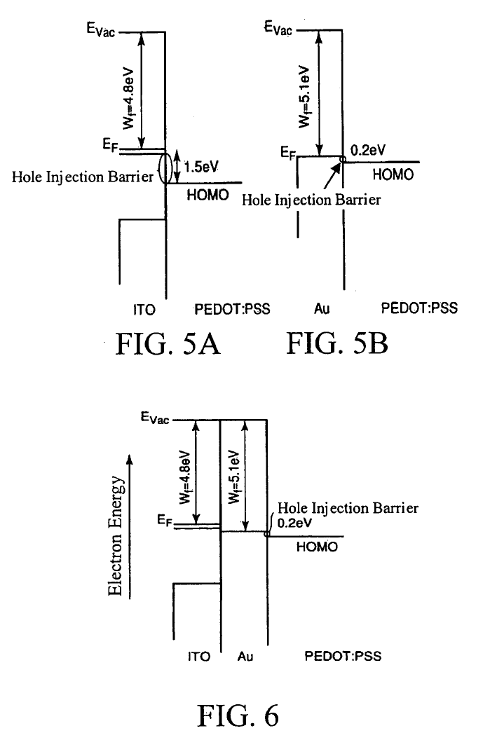

When holes are injected from the positive electrode into the hole transport layer by applying a voltage between the positive and negative electrodes of the display, the hole injection barrier height can be lowered. That is, the hole injection barrier (Eᵢₙⱼ) between Au (the thin film) and PEDOT: PSS (the hole transport layer), is 0.2 eV as shown in FIG. 5B. While the hole injection barrier (Eᵢₙⱼ) between ITO (a positive electrode) and PEDOT:PSS (the hole transport layer), is 1.5 eV as shown in FIG. 5A.

Therefore, the hole injection barriers (Eᵢₙⱼ) at both the boundary surfaces between ITO (the positive electrode) and Au (the thin film), and between Au (the thin film) and PEDOT:PSS (the hole transport layer), are lower than between ITO (the positive electrode) and PEDOT:PSS (the hole transport layer), as shown in FIG. 6.

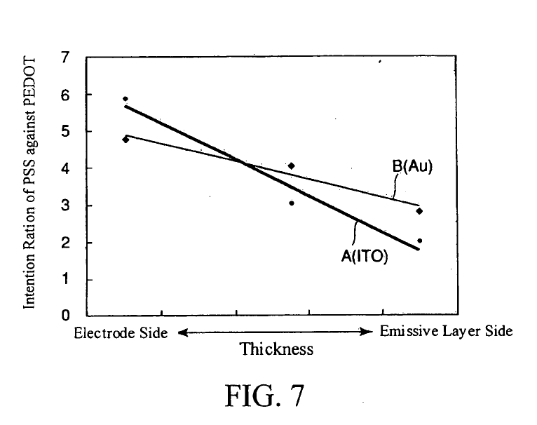

The intensity ratio of PSS against PEDOT, which corresponds to the concentration ratio of PSS inside the hole transport layer from the positive electrode side to the emissive layer side, is analyzed using XPS (X-ray Photoelectron Spectroscopy) as shown in FIG. 7.

When the PEDOT:PSS (the hole transport layer) is directly formed on the ITO (positive electrode), the characteristic line A showing the concentration ratio is steep. When the PEDOT:PSS (the hole transport layer) is formed on the Au thin film, the characteristic line B showing the concentration ratio is more moderate than the line A.

As explicitly shown in FIG. 7, interposing Au, which is more inert than ITO, alleviates the nonuniformity of the distribution of PSS which remains as a dopant inside the hole transport layer. Hence, the hole injection efficiency is enhanced.

Numerous modifications of the present invention are possible in light of the above teachings. It is therefore to be understood that, within the scope of the appended claims, the present invention can be practiced in a manner other than as specifically described herein.

1. An electroluminescent display, comprising:
A transparent substrate;
A transparent positive electrode on the transparent substrate;
An inert metal film on the transparent positive electrode;
A hole transport layer on the inert metal film, the hole transport layer including a conductive polymer doped with a polymeric electrolyte containing a sulfone group; and
An emissive layer on the hole transport layer.

2. An electroluminescent display according to claim 1, further comprising an electron transporting layer on the emissive layer.

3. An electroluminescent display according to claim 2, further comprising a negative electrode on the electron transporting layer.

4. An electroluminescent display according to claim 1, wherein the hole transport layer is formed by coating and drying a solution of the conductive polymer on the inert metal film.

5. An electroluminescent display according to claim 4, wherein the polymeric electrolyte is contained in the solution as a dopant.

6. An electroluminescent display according to claim 1, wherein the inert metal is selected from the group consisting of Au, Pt, Rh and Ir.

7. An electroluminescent display according to claim 6, wherein a thickness of the inert metal film is less than or equal to 3 nm.

8. An electroluminescent display according to claim 6, wherein the inert metal film comprises Au, and a thickness of the inert metal film ranges from 1 to 3 nm.

9. An electroluminescent display according to claim 6, wherein the inert metal film comprises Pt, and a thickness of the inert metal film ranges from 0.5 to 2.5 nm.

10. An electroluminescent display according to claim 6, wherein the inert metal film comprises Rh, and a thickness of the inert metal film ranges from 0.5 to 2.0 nm.

11. An electroluminescent display according to claim 6, wherein the inert metal is Ir, and the thickness thereof is ranging from 0.5 to 2.0 nm.

12. An electroluminescent display according to claim 1, wherein the polymeric electrolyte is poly(4-styrenesulfonate).

13. An electroluminescent display according to claim 1, wherein the conductive polymer is poly (3,4-ethylenedioxythiophene).

14. An electroluminescent display according to claim 1, wherein the transparent substrate comprises glass.

15. A method for manufacturing an electroluminescent display, comprising:
providing a transparent positive electrode on a transparent substrate;
providing a hole transport layer on the positive electrode, the hole transport layer including a conductive polymer doped with a polymeric electrolyte including a sulfone group; and
providing an emissive layer on the hole transport layer.

16. A method for manufacturing an electroluminescent display according to claim 15, further comprising providing an electron transport layer on the emissive layer.

17. A method for manufacturing an electroluminescent display according to claim 16, further comprising providing a negative electrode on the electron transport layer.

18. A method for manufacturing an electroluminescent display according to claim 15, wherein providing the hole transport layer includes coating and drying a solution of the conductive polymer on the inert metal film.

19. A method for manufacturing an electroluminescent display according to claim 15, wherein providing the inert metal film includes providing the inert metal film selected from the group consisting of Au, Pt, Rh and Ir.

20. A method for manufacturing an electroluminescent display according to claim 19, wherein providing the inert metal film includes providing the inert metal film with a thickness less than or equal to 3 nm.
